(19) United States
(12) Patent Application Publication
(10) Pub. No.: US 2012/0056513 A1
(43) Pub. Date: Mar. 8, 2012

(54) TUNING-FORK TYPE QUARTZ-CRYSTAL VIBRATING PIECES AND QUARTZ-CRYSTAL DEVICES COMPRISING SAME

(75) Inventor: Shunsuke Ueno, Saitama (JP)

(73) Assignee: Nihon Dempa Kogyo Co., LTD.

(21) Appl. No.: 13/219,527

(22) Filed: Aug. 26, 2011

(30) Foreign Application Priority Data
Sep. 3, 2010 (JP) JP 2010-198050

(51) Int. Cl. H01L 41/047; H01L 41/053

(52) U.S. Cl. 310/344; 310/364

(57) ABSTRACT

Tuning-fork type quartz-crystal vibrating pieces are disclosed that exhibit low CI and low interconnection resistance. An exemplary vibrating piece includes vibrating arms extending in a predetermined direction from a base, respective excitation electrodes, a base connected to the vibrating arms, respective supporting arms disposed outboard of respective vibrating arms and extending from the base in the predetermined direction, and respective extraction electrodes connected to respective excitation electrodes. Each excitation electrode comprises two metal layers, including a first metal layer comprising at least one metal selected from Cr, Ni, Ti, Al and W, and a second metal layer overlying the first metal layer and comprising Au or Ag. Each extraction electrode comprises four metal layers, namely the first and second metal layers, a third metal layer overlying the second metal layer and comprising at least one metal selected from Cr, Ni, Ti, Al and W, and a fourth metal layer overlying the third metal layer and comprising Au or Ag.

### CROSS-REFERENCE TO RELATED APPLICATION

This application claims priority to and the benefit of Japan Patent Application No. 2010-198050, filed on Sep. 3, 2010, in the Japan Patent Office, the disclosure of which is incorporated herein by reference in its entirety.

### FIELD

This disclosure pertains to, inter alia, tuning-fork type quartz-crystal vibrating pieces and to quartz-crystal vibrating devices comprising same. More particularly, this disclosure pertains to such pieces and devices exhibiting desirable low CI (crystal impedance).

### DESCRIPTION OF THE RELATED ART

In certain types of quartz-crystal vibrating devices, a tuning-fork type quartz-crystal vibrating piece is enclosed within a “package” to form a crystal-vibrating device. Conventionally, metal-film electrodes (e.g., excitation electrodes) used on the tuning-fork type quartz-crystal vibrating piece comprise a layer of Cr (as a foundation layer) and an overlying layer of Au. The excitation electrodes are normally connected to corresponding connecting electrodes on the package by electrically conductive adhesive. A flip-chip bonding method (involving use of ultrasonic bonding) can be used for bonding the connecting electrodes on the tuning-fork type quartz-crystal vibrating piece to corresponding connecting electrodes on the package. Unfortunately, the connecting electrodes on the vibrating piece and the connecting electrodes on the package frequently encounter compatibility problems such as Cr atoms in the connecting electrodes on the vibrating piece migrating to the Au layer, or Au atoms become absorbed into the Cr layer. These phenomena can cause peeling of the connecting electrodes on the vibrating piece and the connecting electrodes on the package.

Japan Unexamined Patent Document No. 2007-96899 discusses a method of forming a thicker layer of Au on top of the connecting electrode on the vibrating piece, while also reducing the bump reaching Cr by thickening the Au layer. However, in the vibrating piece discussed in JP '899, only the Au layer on the connecting electrodes is thickened, which requires adjusting the flip-chip bonding so that it does not extend into the underlying Cr foundation layer.

Tuning-fork type quartz-crystal vibrating pieces and quartz-crystal devices as disclosed herein exhibit low CI values and low interconnection resistance.

### SUMMARY

According to a first aspect of the invention, tuning-fork type quartz-crystal vibrating pieces are provided. In an embodiment, the quartz-crystal vibrating piece is contained inside a package and bonded to respective connecting electrodes inside the package. The vibrating piece comprises a pair of vibrating arms extending in a predetermined direction and having respective excitation electrodes. The vibrating arms are connected to a base. First and second supporting arms are disposed outboard of respective vibrating arms. Each supporting arm extends from the base in the predetermined direction. Respective extraction electrodes extend from an edge region of each supporting arm to the respective excitation electrode. Each excitation electrode comprises a first metal layer comprising at least one metal selected from Cr, Ni, Ti, Al and W. A second metal layer overlies the first metal layer and comprises Au or Ag. Each extraction electrode further comprises a third metal layer overlying the second metal layer and comprising at least one metal selected from Cr, Ni, Ti, Al and W, and a fourth metal layer overlying the third metal layer, wherein the fourth metal layer comprises Au or Ag. In certain embodiments the second metal layer has a thickness in a range of 40 nm to 60 nm (400 Å to 600 Å), and the fourth metal layer has a thickness of at least 60 nm (600 Å).

An embodiment of a quartz-crystal “device” comprises a tuning-fork type quartz-crystal vibrating piece as summarized above and respective external electrodes situated on an exterior surface of the package and connected to respective excitation electrodes in the package.

A tuning-fork type quartz-crystal vibrating piece according to another embodiment includes an outer frame bonded peripherally to a package base and further includes respective connecting electrodes. The vibrating piece comprises first and second supporting arms connected to the outer frame, and a base connected to the supporting arms. First and second vibrating arms are situated inboard of the respective supporting arms. Each vibrating arm extends from the base and includes respective excitation electrodes. Respective extraction electrodes are electrically connected to respective excitation electrodes. The extraction electrodes are situated on the base, the respective supporting arms, and the outer frame. Each excitation electrode comprises a first metal layer at least one metal selected from Cr, Ni, Ti, Al and W. A second metal layer overlies the first metal layer and comprises Au or Ag. Each extraction electrode further comprises a third metal layer overlying the second metal layer and comprising at least one metal selected from Cr, Ni, Ti, Al and W. A fourth metal layer overlies the third metal layer and comprises Au or Ag.

An embodiment of a quartz-crystal “device” comprises a quartz-crystal vibrating piece as summarized above, a package base bonded onto a first surface of the outer frame, and a package lid bonded onto a second surface of the outer frame.

Tuning-fork type quartz-crystal vibrating pieces and quartz-crystal devices as disclosed herein exhibit low interconnection resistances and low CI values. These features are obtained by forming the extraction electrodes to the connecting electrodes out of four superposed metal layers, and by forming the excitation electrodes of two superposed metal layers. Even if a flip-chip bonding method is used to assemble the devices, depletion of Au is avoided due to the presence of a layer of Au beneath the Cr layer.

### BRIEF DESCRIPTION OF THE DRAWINGS

FIG. 1A is a plan view of the first embodiment of a tuning-fork type quartz-crystal vibrating piece.

FIG. 1B is an elevational section along the line A-A′ in FIG. 1A.

FIG. 2A is a plan view of the first embodiment of a quartz-crystal device.

FIG. 2B is an elevational section along the line B-B′ in FIG. 2A.

FIG. 3 is a flow-chart of a method for manufacturing the first embodiment of a quartz-crystal device.

FIG. 4 is a graph showing the relationship between the thickness of the gold (Au) layer on the excitation electrode versus the CI value.

FIG. 5A is a flow-chart of a method for manufacturing the extraction electrodes used on a quartz-crystal device of the first embodiment.

FIG. 5B is a flow-chart of a method for manufacturing the extraction electrodes used on a quartz-crystal device of the second embodiment.

FIG. 6A is an exploded perspective view of the second embodiment of a quartz-crystal device.

FIG. 6B is an elevational section of the second embodiment of a quartz-crystal device along the line C-C′ in FIG. 6A.

FIG. 7A is a plan view of an embodiment of a quartz-crystal frame 20.

FIG. 7B is an elevational section of the quartz-crystal frame, along the line D-D′ of FIG. 7A.

### DETAILED DESCRIPTION

Various embodiments are described in detail below, with reference to the accompanying drawings. In the described embodiments, the direction in which the vibrating arms of the tuning-fork type quartz-crystal vibrating piece extend is the Y-axis direction. The width direction of the vibrating arms is the X-axis direction. The direction normal to both the X-axis and Y-axis directions is the Z-axis direction.

### First Embodiment of Quartz-Crystal Vibrating Piece

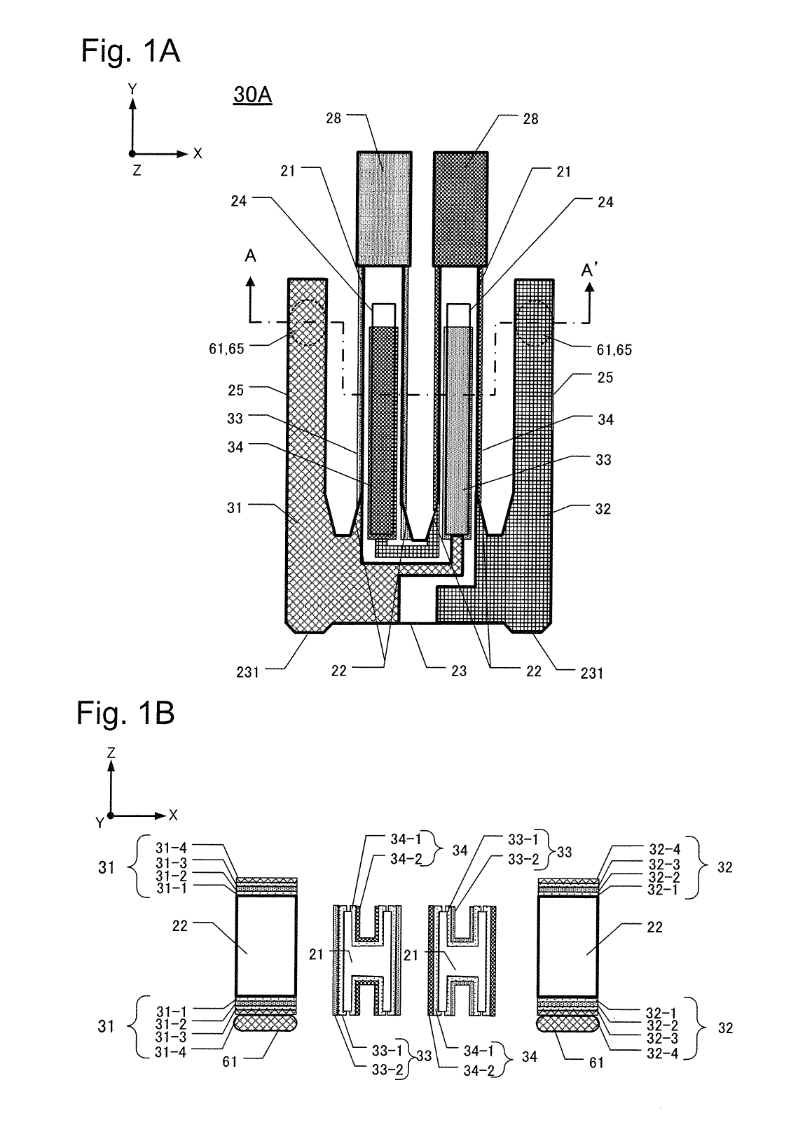

FIG. 1A is a plan view of this embodiment of a tuning-fork type quartz-crystal vibrating piece 30A. FIG. 1B is an elevational section along the line A-A′ in FIG. 1A. The first embodiment of a tuning-fork type quartz-crystal vibrating piece 30A comprises a pair of vibrating arms 21, a pair of supporting arms 25, and a base 23. As shown in FIG. 1A, the base 23 has a board-like configuration. The vibrating arms 21 extend from the base 23 parallel to each other in the Y-axis direction and at a substantially constant width. The distal end of each vibrating arm 21 is wider than other portions of the arm, and includes a respective weight 28. The weights 28 facilitate ease of vibration of the arms whenever an appropriate voltage is applied to the vibrating arms 21, and facilitate making adjustments of the vibration frequency of the tuning-fork type quartz-crystal vibrating piece 30A. This embodiment of a vibrating piece 30A vibrates at, for example, 32.768 kHz.

Near the base, the width of the vibrating arms 21 progressively increases at base portions 22 thereof. The base portions 22 also vibrate. Since they are wider than other portions most of the vibrating arms, the base portions 22 concentrate stress, normally in the vibrating arms 21 toward the base portions 22. This stress concentration reduces leakage of vibration to the base 23. Each vibrating arm 21 includes a respective excitation electrode 33, 34.

The vibrating arms 21 extend parallel to each other in Y-axis direction from the base 23. Each vibrating arm includes a respective groove 24 formed on both the upper and lower surface thereof. For example, one groove 24 is formed on the upper surface of each vibrating arm 21, and a second groove 24 is formed on the lower surface of each vibrating arm 21. As shown in FIG. 1B, the grooves 24 provide each vibrating arm 21 with an H-shaped cross-section. The grooves 24 desirably decrease the CI of the vibrating piece 30A, and are similar in the second embodiment as well (see below).

Outboard of each vibrating arm 21 is a respective supporting arm 25. Each supporting arm 25 extends from a respective edge of the base 23 in the Y-axis direction. The supporting arms 25 are shorter than the vibrating arms 21. The supporting arms 25 decrease the effect on the vibrating arms 21 of vibration leakage and changes in the exterior environment. Each supporting arm 25 includes a respective bonding portion 65 near the distal end of the respective supporting arm 25. Using the bonding portions 65, the vibrating piece 30A is bonded to respective locations of the package using an electrically conductive adhesive 61. The first embodiment of a vibrating piece 30A and the package can be bonded together by a flip-chip bonding method.

On each supporting arm 25 is a respective extraction electrode 31, 32 connected to the respective excitation electrode 33, 34. The extraction electrodes 31, 32 extend to the base 23 as well.

As shown in FIG. 1B, each of the excitation electrodes 33, 34 comprises two metal layers. One excitation electrode 33 includes first and second metal layers 33-1, 33-2, and the other excitation electrode 34 includes first and second metal layers 34-1, 34-2. The first metal layer 33-1 is formed on the upper and lower quartz-crystalline surfaces of a first vibrating arm 21 and on the side-edge surfaces of the second vibrating arm. The second metal layer 33-2 overlies the first metal layer 33-1 in these locations. Meanwhile, the first metal layer 34-1 is formed on the upper and lower quartz-crystalline surfaces of the second vibrating arm 21 and on the side-edge surfaces of the first vibrating arm 21, and the second metal layer 34-2 overlies the first metal layer 34-1 in these locations. Each first metal layer 33-1, 34-1 comprises at least one metal selected from Cr, Ni, Ti, Al, and W. Each second metal layer 33-2, 34-2 comprises at least one metal selected from Au and Ag.

Each extraction electrode 31, 32 comprises four metal layers, including a first metal layer 31-1, 32-1, respectively, formed on the surface of the quartz-crystal material, and a second metal layer 31-2, 32-2, respectively, overlying the first metal layer. A third metal layer 31-3, 32-3, respectively, overlies the second metal layer, and a fourth metal layer 31-4, 32-4, respectively, overlies the third metal layer. The first and second metal layers are similar to the first and second metal layers 33-1, 33-2 and 34-1, 34-2, respectively. Each of the third metal layers 31-3, 32-3 comprises at least one metal selected from Cr, Ni, Ti, Al, and W, and each of the fourth metal layers 31-4, 32-4 comprises at least one metal selected from Au and Ag.

### Fabrication of the First Embodiment of Quartz-Crystal Device

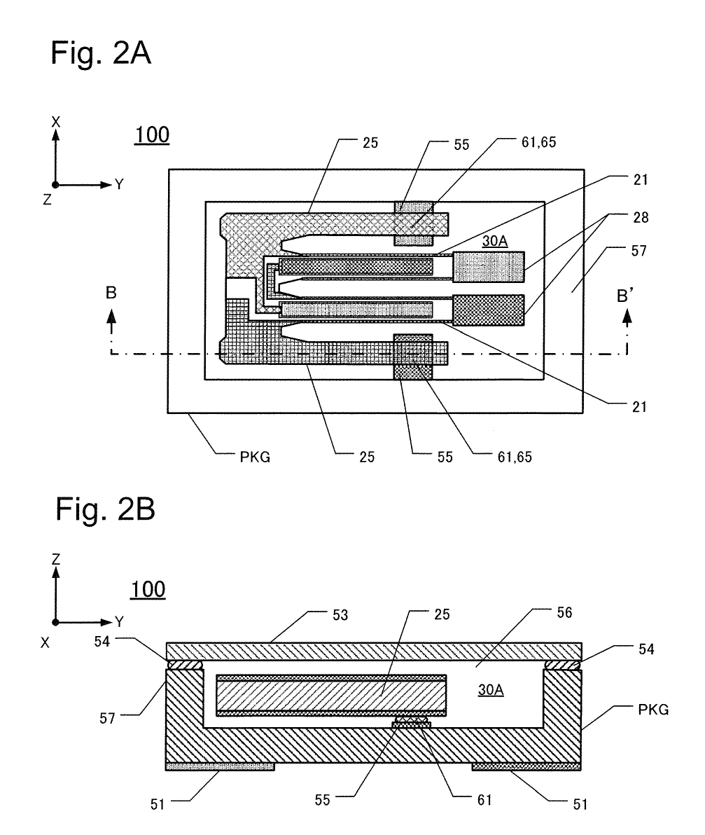

FIG. 2A is a top plan view of the first embodiment of a quartz-crystal device 100 from which the lid 53 has been removed, and FIG. 2B is an elevational section along the B-B′ line in FIG. 2A. The quartz-crystal device 100 comprises a tuning-fork type quartz-crystal vibrating piece 30A contained within a cavity 56 defined in a package PKG, of which the lid 53 and package PKG are bonded together under a vacuum using a sealing material 54.

The lid 53 is fabricated of a metal such as kovar alloy or borosilicate glass. The package PKG is fabricated of a glass or ceramic material, the latter being formed by stacking multiple layers of ceramic sheets into a box shape. External electrodes 51 are situated on the lower main surface of the package PKG. The package PKG is a surface-mountable (SMD) type.

Bonding pads 55 are situated on the package PKG in respective positions corresponding to the positions of the bonding portions 65 of the supporting alms 25. The tuning-fork type quartz-crystal vibrating piece 30A is bonded to the bonding pads 55 using an electrically conductive adhesive 61. Specifically, the adhesive 61 is applied to the bonding pads 55, followed by placement of the bonding portions 65 on top of the electrically conductive adhesive 61. Then, the adhesive 61 is subjected to preliminary-curing conditions. Later, the electrically conductive adhesive 61 is cured in a hardening furnace to bond the tuning-fork type quartz-crystal vibrating piece 30A onto the bonding portions 65 of the package PKG. Thus, the excitation electrodes on the tuning-fork type quartz-crystal vibrating piece 30A are electrically connected to respective external electrodes 51 outside the package PKG.

The vibration frequency of the quartz-crystal device 100 is adjusted by irradiating a laser beam to the weights 28 formed on distal ends of the vibrating arms 21, to evaporate a desired amount of the metal from the weights 28. If the lid 53 is fabricated of a material (e.g., borosilicate glass) that transmits the laser beam, the vibration frequency of the device can be adjusted using a laser even after sealing the lid 53 to the package PKG. The quartz-crystal device 100 is manufactured according to good quality assurance practices.

### Embodiment of Method for Manufacturing First Embodiment of Quartz-Crystal Device

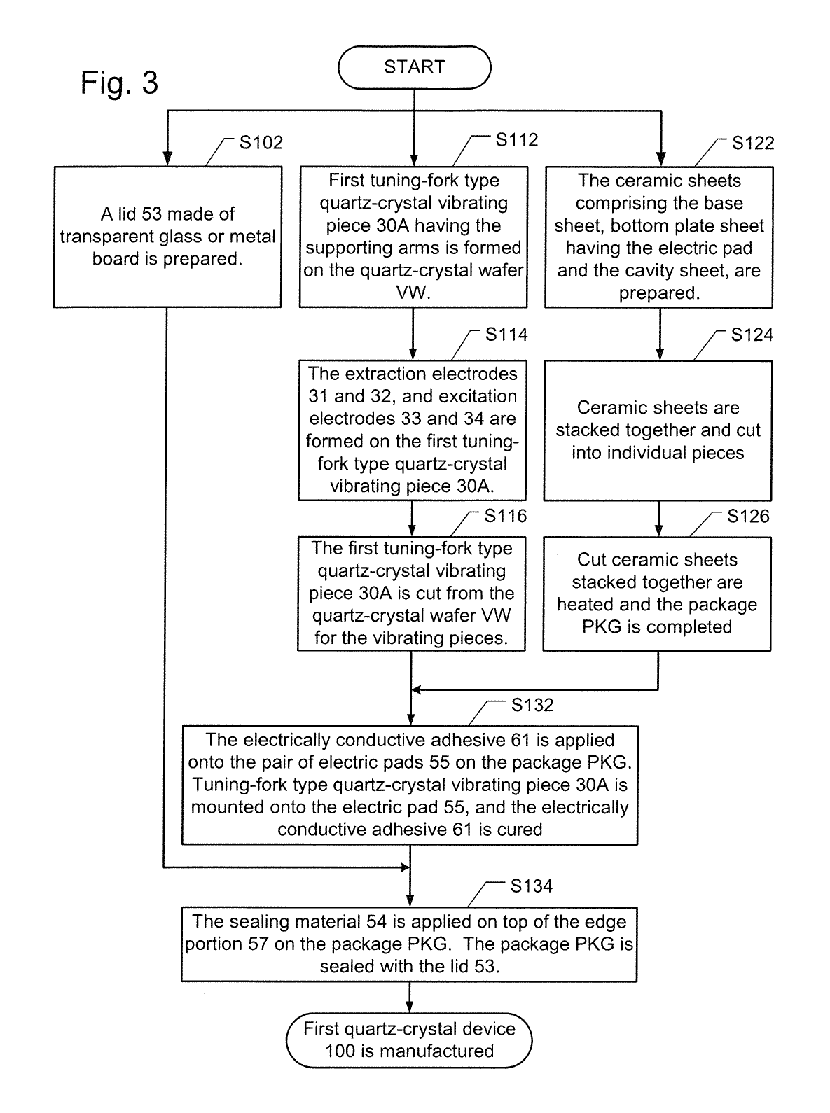

FIG. 3 is a flow-chart of steps in an embodiment of a method for manufacturing quartz-crystal devices 100. Manufacture of tuning-fork type quartz-crystal vibrating pieces 30A is according to steps S112 to S116 in the method.

In step S112, a tuning-fork type quartz-crystal vibrating piece 30A having supporting arms is formed on a quartz-crystal wafer VW (on which multiple vibrating pieces 30A are formed simultaneously). The profile outlines of the vibrating pieces 30A (as well as of the grooves 24 on the vibrating arms) are formed by photolithography and etching, which is a common technique for such purpose. Subsequent etching of the profile outlines forms multiple profile outlines of the vibrating pieces 30A simultaneously from a circular or angled quartz-crystal wafer. The outline profile of the vibrating piece 30A is etched into the quartz-crystal wafer coated with a patterned anticorrosive film. An exemplary etchant is, for example, hydrofluoric acid. The anticorrosive film can be, for example, a metal sub-layer of Cr and an overlying Au layer formed by vacuum-deposition. While forming the profile outline of the vibrating pieces 30A, the grooves 24 are also formed on the front (upper) and rear (lower) surfaces of the vibrating arms 22.

In step S114, as shown in FIG. 1A, the extraction electrodes 31, 32 and excitation electrodes 33, 34 are formed on the vibrating piece 30A. These electrodes begin with formation of the first metal layers and second metal layers by vacuum-deposition or sputtering. The electrodes are then shaped by photolithography and etching. The first metal layers and second metal layers are also shaped to cover the distal regions of the vibrating arms 21 having greater width, thus forming the weights 28.

The excitation electrodes 33, 34 on the vibrating piece 30A are formed of the first metal layer (e.g., Cr) and overlying second metal layer (e.g., Au). The first metal layers are each formed having a thickness in the range of 15 nm to 60 nm. Instead of Cr, the first metal layer can be at least one of Cr, Ni, Ti, Al and W. The second metal layers are formed having a thickness of 40 nm to 60 nm. Instead of Au, the second metal layer can be Ag.

On the extraction electrodes 31, 32, the third metal layers and fourth metal layers overlie the first metal layers and second metal layers, thus forming a four-layer superposed stack of layers. The extraction electrode 31 comprises the first metal layer 31-1, the second metal layer 31-2, the third metal layer 31-3 and the fourth metal layer 31-4 (FIG. 1B). The extraction electrode 32 comprises the first metal layer 32-1, the second metal layer 32-2, the third metal layer 32-3 and the fourth metal layer 32-4 (FIG. 1B). The third metal layers are formed of Cr or, alternatively, at least one metal layer selected from Ni, Ti, Al and W. The fourth metal layers are made of at least one of Au and Ag. The thickness of the third metal layer made of Cr is in the range of 15 nm to 60 nm. The thickness of the fourth metal layer made of Au or Ag is in the range of 60 nm to 200 nm.

In step S116 the vibrating pieces 30A are cut from the quartz-crystal wafer VW, to separate them and produce multiple individual vibrating pieces. Since each vibrating piece 30A is connected to the quartz-crystal wafer by a respective connecting portion 231 on the base 23 (FIG. 1), the individual vibrating pieces are cut from the crystal wafer VW at the connecting portions 231.

Fabrication of the package PKG is performed by executing the steps S122 to S126. In step S122, multiple ceramic sheets are stacked to form the package PKG. These sheets include a base sheet, a bottom-plate sheet, and at least one cavity sheet to define the side walls 57 of each package. On the bottom plate sheet a tungsten paste is applied by screen-printing to form the electric pads 55. Similarly, on the base sheet a tungsten paste is applied by screen-printing to form the external electrodes 51.

In step S124 the base sheet, bottom-plate sheet, and cavity sheet are stacked together. The stacked ceramic sheets are then cut into the size of individual packages PKG.

In step S126 the cut packages PKG are heated to approximately 1320° C. to fire the package ceramic, thereby completing formation of the package PKG.

In step S132, electrically conductive adhesive 61 is applied to the electric pads 55 on the package PKG. A vacuum apparatus (not shown) is employed in this step to facilitate attachment of the tuning-fork type quartz-crystal vibrating piece 30A. The vibrating pieces are stored under a vacuum until time to be mounted in the packages PKG. Each vibrating piece 30A is then mounted on the electric pads 55 in a respective package PKG, which is positioned to receive a corresponding bonding portion 65 of the supporting arms 25 of the vibrating piece. The electrically conductive adhesive is then cured to produce tuning-fork type quartz-crystal vibrating pieces 30A each being affixed to the electrical pads 55.

In step S134 a sealing material 54 is applied on the upper main surface (bonding surface) of the edge walls 57 on the package PKG. The lid 53 is placed on top of the applied sealing material. The resulting assembly is heated at approximately 350° C. under a vacuum or in an inert-gas atmosphere, together with compression of the lid 53 and package PKG together to achieve bonding of the lid to the package. Following these steps, further quartz-crystal vibrating devices 100 are manufactured, pending the outcome of a quality check.

### Electrode Formation

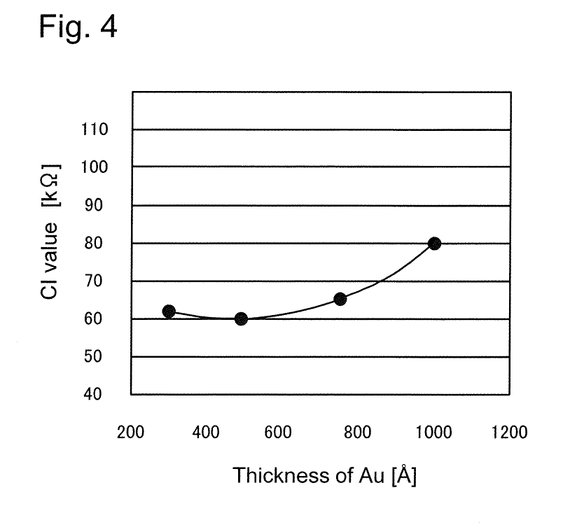

In step S114, the thickness of Au in the second metal layer is in the range of approximately 40 nm to 60 nm (400 Å to 600 Å). FIG. 4 is a graph showing the relationship between the thickness of Au in the excitation electrodes 33, 34 versus the CI (kΩ) of the device. The abscissa of the graph is Au thickness (Å) and the ordinate of the graph is CI. The CI values plot as a parabolic curve against the Au thickness. The thickness of Au in the electrodes 33, 34 desirably is in the range of 40 nm to 60 nm, so as to provide decreased CI value.

With decreasing thickness of Au in the extraction electrodes 31, 32, interconnection resistance increases. This relationship tends to form a straight-line graph. Thus, interconnection resistance increases with corresponding increases in the thickness of Au. Hence, vibrating devices 100 desirably are produced having low interconnection resistance values and low CI values. This is achieved by keeping the thickness of the second metal layer (Au) of the excitation electrodes 33, 34 between 40 nm to 60 nm, and by forming the fourth metal layers (Au) of the extraction electrodes 31, 32 to have a thickness in the range of 60 nm to 200 nm.

In this embodiment, each quartz-crystal vibrating piece 30A and corresponding package PKG are bonded together using electrically conductive adhesive 61. Even if the vibrating piece 30A is bonded to the package PKG using a flip-chip bonding method, the presence of the second metal layer of Au beneath the third metal layer prevents the second metal layer of Au from being degrading by out-migration of Au under a vacuum condition.

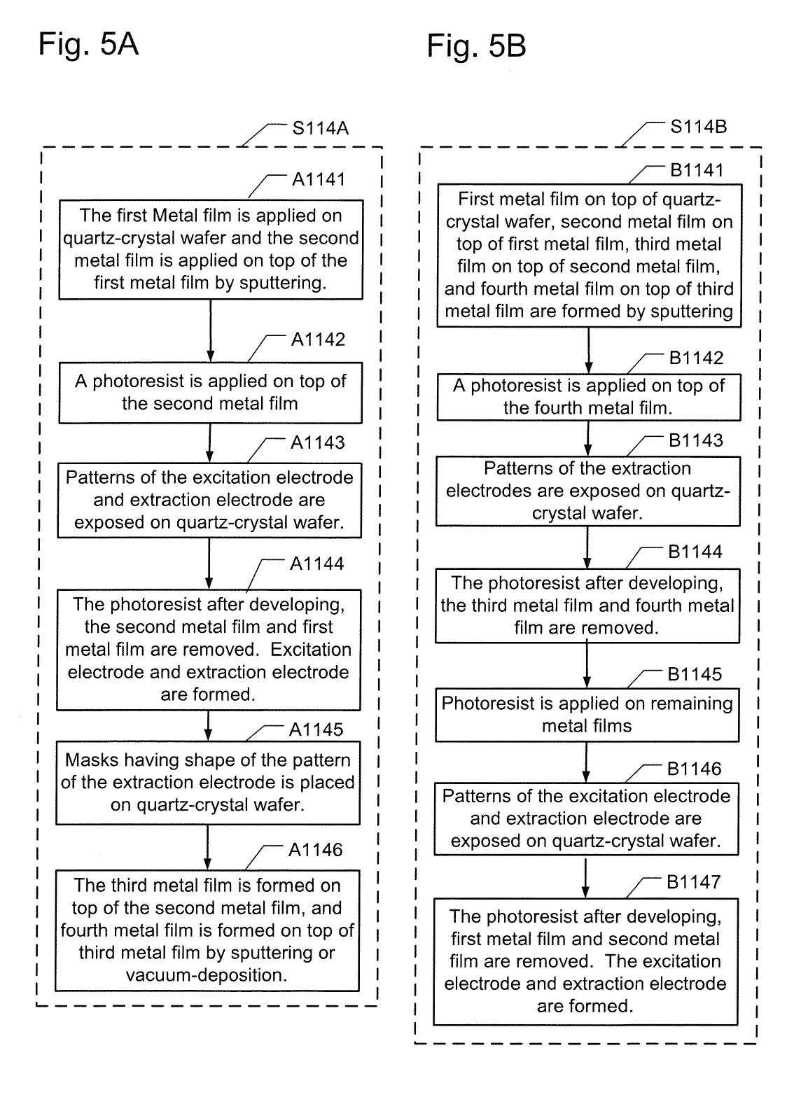

FIGS. 5A and 5B are flow-charts of an embodiment of a method S114A for forming the extraction electrodes 31, 32 and the excitation electrodes 33, 34. The methods shown in FIGS. 5A and 5B are detailed descriptions of step S114.

In step A1141, the first metal layers (Cr) having a thickness in the range of 15 nm to 60 nm and the second metal layers (Au) having a thickness in the range of 40 nm to 60 nm are formed on both surfaces of a quartz-crystal wafer. The wafer thus defines quartz-crystal vibrating pieces 30A each having a pair of supporting arms. The metal layers are applied by sputtering or vacuum-deposition.

In step A1142, a photoresist is uniformly applied onto both surfaces of the quartz-crystal wafer on which the first and second metal layers have been formed.

In step A1143, using an exposure tool (not shown), profiles of the excitation electrodes and the extraction electrodes are exposed onto the photoresist film. The electrode patterns are exposed on both surfaces of the quartz-crystal wafer.

In step A1144, the exposed photoresist film on the quartz-crystal wafer is developed and the exposed photoresist is removed. Portions of the second metal layers (Au) denuded by corresponding voids in the photoresist film are etched away using an aqueous solution of, e.g., iodine and potassium iodide. Then, portions of the first metal layer (Cr) denuded by removing Au are etched away using an aqueous solution of, for example, ceric ammonium nitrate and acetic acid. The concentration, temperature, and duration of exposure to the aqueous solution are predetermined and adjusted as required to prevent unnecessary etching of other regions. Thus, the quartz-crystal wafer containing multiple tuning-fork type quartz-crystal vibrating pieces 30A, each having extraction electrodes 31, 32 and excitation electrodes 33, 34, is formed. However, the extraction electrodes 31, 32 formed in step A1144 still have only two layers.

In step A1145, masks having voids defining the shapes of the extraction electrodes 31, 32 are placed on the quartz-crystal wafer. The masks are placed on both surfaces of the wafer.

In step A1146, third metal layers (Cr), having a thickness in the range of 15 nm to 60 nm, are formed on the second metal layers by sputtering or vacuum-deposition through the openings in the masks. This is followed by formation of the overlying fourth metal layers (Au), each having a thickness in the range of 60 nm to 200 nm, on the third metal layers by sputtering or vacuum deposition through the openings in the masks.

Thus, a quartz-crystal wafer containing multiple tuning-fork type quartz-crystal vibrating pieces 30A of the first embodiment is formed. Each vibrating piece has extraction electrodes 31, 32 formed of four metal layers stacked together, and extraction electrodes 33, 34 formed of two metal layers stacked together.

FIG. 5B is a flow-chart of a second embodiment S114B of a method for forming the extraction and excitation electrodes. The difference of this method from that described in FIG. 5A is that, in the second embodiment, the first, second, third, and fourth metal layers are formed on the quartz-crystal wafer by sputtering or vacuum-deposition first, followed by etching to form the excitation electrodes and extraction electrodes.

In step B1141, the first metal layers (Cr) having thickness in the range of 15 nm to 60 nm, the second metal layers (Au) having thickness in the range of 40 nm to 60 nm, the third metal layers (Cr) having thickness in the range of 15 nm to 60 nm, and the fourth metal layers (Au) having thickness in the range of 60 nm to 200 nm are formed on both surfaces of a quartz-crystal wafer by sputtering or vacuum-deposition. The wafer already has outlines of the first embodiment of the tuning-fork type quartz-crystal vibrating pieces 30A.

In step B1142, a photoresist is applied to both surfaces of the quartz-crystal wafer.

In step B1143, using an exposure tool (not shown), respective patterns of the extraction electrodes (the electrode patterns except for those of the extraction electrodes are etched) are exposed on the photoresist film. The electrode patterns are exposed on both surfaces of the quartz-crystal wafer.

In step B1144, the photoresist film on the quartz-crystal wafer is developed and the exposed photoresist is removed. Denuded regions of the fourth metal layers (Au) are etched. Then, regions of the third metal layers (Cr) denuded by removal of Au are etched. In step B1144, denuded regions of the fourth metal layers (Au) and the third metal layers (Cr) situated in regions corresponding to the excitation electrodes are etched as well.

In step B1145, after removing the entire photoresist film, another photoresist film is applied onto remaining metal layers on both surfaces of the quartz-crystal wafer.

In step B1146, using an exposure tool (not shown), the patterns of the excitation electrodes and extraction electrodes are formed on both surfaces of the photoresist film. (Electrode patterns except for extraction electrodes are etched.)

In step B1147, the photoresist film on the quartz-crystal wafer is developed, followed by etching of denuded regions of the second metal layers (Au). Then, the denuded first metal layers (Cr) are etched. Thus, the extraction electrodes 31, 32, each formed of a four-layer stack of the first, second, third, and fourth metal layers, and the excitation electrodes 33, 34 each formed of a two-layer stack of the first and second metal layers, are formed on the quartz-crystal wafer.

### Second Embodiment of Quartz-Crystal Device

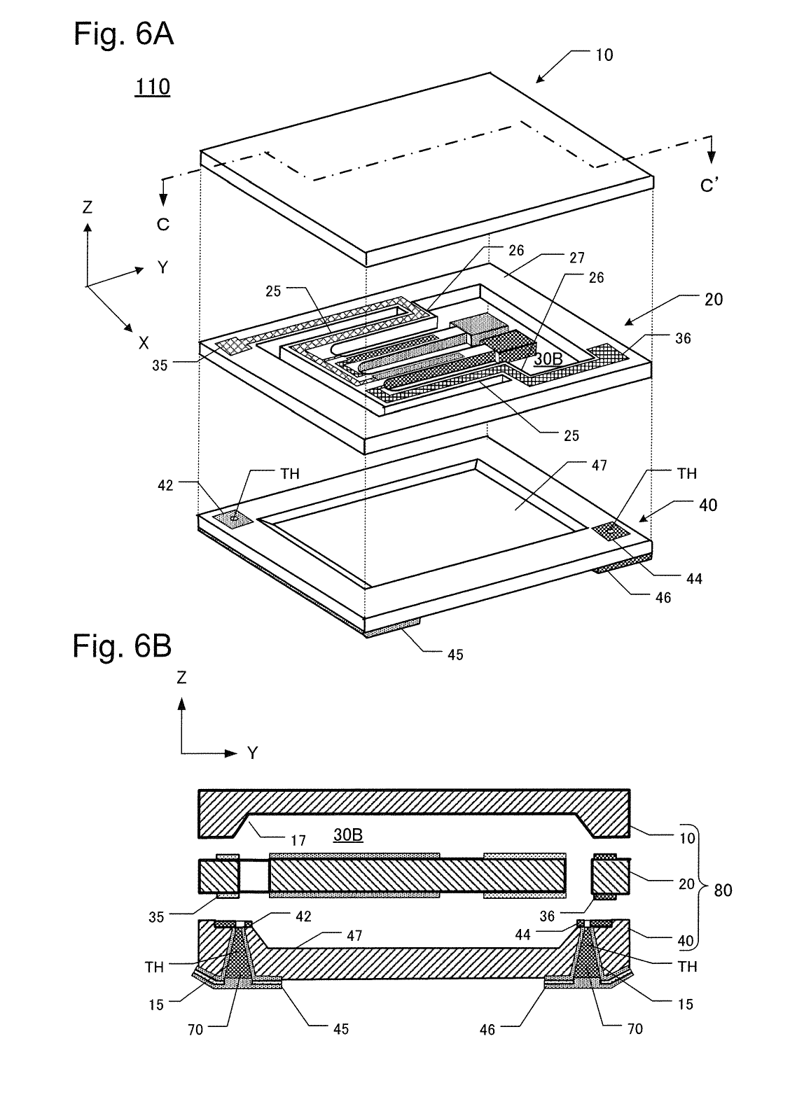

FIG. 6A is an exploded perspective view of a second embodiment of a quartz-crystal device 110. FIG. 6B is an elevational section, along the line C-C′ in FIG. 6A, of the device shown in FIG. 6A. In FIG. 6B the constituent parts are shown separated from each other vertically. The device shown in FIG. 6A is a surface-mountable (SMD) type quartz-crystal device 110.

As shown in FIG. 6A, the second embodiment of a quartz-crystal device 110 comprises a package 80, including a quartz-crystal package lid 10, the second embodiment of a tuning-fork type quartz-crystal vibrating piece 30B with surrounding quartz-crystal frame 20, and a quartz-crystal package base 40. The package lid 10, the vibrating piece 30B and frame 20, and the package base 40 are all made in quantity simultaneously on respective quartz-crystal wafers.

The package base 40 comprises a first external electrode 45 and a second external electrode 46 located on the bottom (external) surface thereof. The package base 40 also defines a base recess 47 on the upper (inner) main surface thereof, facing the quartz-crystal frame 20. The package base 40 also defines respective through-holes TH for the first connecting electrode 42 and second connecting electrode 44. The first connecting electrode 42 is connected to the first external electrode 45 via a through-hole interconnection 15 extending through the through-hole TH. Similarly, the second connecting electrode 44 is connected to the second external electrode 46 via a through-hole interconnection 15 extending through the through-hole TH.

As shown in FIG. 6B, the package lid 10 defines a lid recess 17 on the lower (inner) main surface thereof, facing the quartz-crystal frame 20.

The quartz-crystal frame 20 comprises the tuning-fork type quartz-crystal vibrating piece 30B having a base 23, vibrating arms 21, respective supporting arms 25, extraction electrodes 31, 32, and respective connecting portions 26. The frame 20 also includes an outer frame 27. The quartz-crystal frame 20 is placed on the package base 40 and has substantially uniform thickness.

The quartz-crystal frame 20 also comprises connecting terminals 35, 36 on both main surfaces of the outer frame 27. The connecting terminals 35, 36 on the lower main surface of the outer frame 27 are connected to respective first and second connecting electrodes 42, 44 located on the upper main surface of the package base 40. Thus, the connecting terminal 35 is electrically connected to the first external electrode 45, and the connecting terminal 36 is electrically connected to the second external electrode 46.

The quartz-crystal frame 20 including the vibrating piece 30B is disposed between (sandwiched by) the package lid 10 and package base 40. The package lid 10 is bonded to a peripheral region on the upper main surface of the quartz-crystal frame 20, and the package base 40 is bonded to a peripheral region on the lower main surface of the quartz-crystal frame 20. The package base 40 is bonded to the quartz-crystal frame 20, and the package lid 10 is bonded to the quartz-crystal frame 20, by siloxane (Si—O—Si) bonding. After siloxane bonding, a eutectic alloy of Au and Sn (lead) or a eutectic alloy 70 of Au and Ge (germanium) is applied to fill and seal the interiors of the through-holes TH. This alloy can be stored in the reflow chamber (not shown) and melted as required for sealing the package together.

### Quartz-Crystal Frame

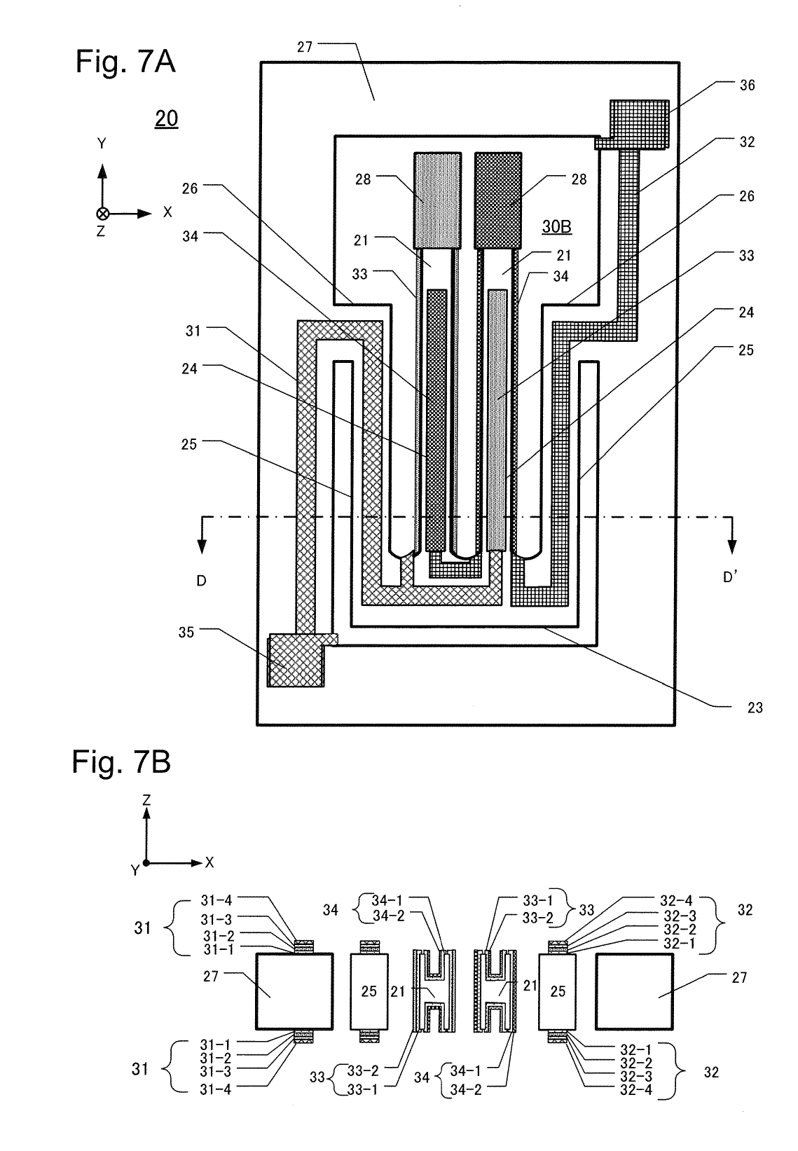

FIG. 7A is a plan view of the quartz-crystal frame 20, and FIG. 7B is an elevational section (along the line D-D′) of FIG. 7A. This embodiment of a tuning-fork type quartz-crystal vibrating piece 30B oscillates (vibrates) at a frequency of, for example, 32.768 kHz. In this figure, the same reference numerals are used for similar respective features as in the first embodiment of a tuning-fork type quartz-crystal vibrating piece 30A, and further description of those features is not provided below.

On the main surface of the frame portion 27 shown in FIG. 7A, the base 23, the supporting arms 25, and connecting portion on the frame 20, the extraction electrodes 31, 32 and connecting electrodes 35, 36 are formed. Similarly, the extraction electrodes 31, 32 and connecting electrodes 35, 36 are formed on the reverse main surface. The connecting electrodes 35, 36 on the depicted main surface are connected to the connecting electrodes 35, 36 on the reverse main surface.

On the vibrating arms 21, the excitation electrodes 33, 34 are formed on the depicted main surface, the reverse main surface, and the side (edge) surfaces. The excitation electrode 33 is connected to the connecting electrode 35, and the excitation electrode 34 is connected to the connecting electrode 36.

Turning to FIG. 7B, the excitation electrodes 33, 34 each comprise two layers of metal, including the first metal layer and the second metal layer. The excitation electrode 33 includes the first metal layer 33-1 and the second metal layer 33-2. The excitation electrode 34 includes the first metal layer 34-1 and the second metal layer 34-2. Both excitation electrodes 33, 34 have a foundation layer of Cr having a thickness in the range of 15 nm to 60 nm and an overlying layer of Au having a thickness of 40 nm to 60 nm. Alternatively to Cr, the foundation layer may be selected from at least one of Cr, Ni, Ti, Al and W; alternatively to Au, Ag can be used.

The connecting electrodes 35, 36, and the extraction electrodes 31, 32 include the third metal layer and fourth metal layer that overlie the second metal layer. Thus, these electrodes comprise four metal layers. The extraction electrode 31 comprises the first metal layer 31-1, the second metal layer 31-2, the third metal layer 31-3, and the fourth metal layer 31-4. The extraction electrode 32 comprises the first metal layer 32-1, the second metal layer 32-2, the third metal layer 32-3 and the fourth metal layer 32-4. The third metal layer is Cr having a thickness in the range of 15 nm to 60 nm; alternatively to Cr, the third metal layer can be selected from at least one of Ni, Ti, Al and W. The fourth metal layer is Au having thickness in the range of 60 nm to 200 nm. Instead of Au, Ag can be used.

Therefore, the second metal layer (Au) of the excitation electrodes 33, 34 has a thickness in the range of 40 nm to 60 nm, and the fourth metal layer (Au) of the extraction electrodes 31, 32 has a thickness in the range of 60 nm to 200 nm. Thus, the quartz-crystal devices 110 exhibit a low interconnection resistance and low CI value. Whenever the eutectic alloy 70 in the through-holes TH melts, Au may be drawn out of the connecting electrodes 35, 36 and from the extraction electrodes 31, 32. However, since an Au layer is situated beneath the third metal layer, the other layer of Au does not experience depletion of Au.

Although the method for manufacturing the quartz-crystal device 110 is not described herein detail, the profile outline of the frame, the extraction electrodes 31, 32, the excitation electrodes 33, 34, and the connecting electrodes 35, 36 are formed as described in FIGS. 3 and 5.

### INDUSTRIAL APPLICABILITY

Representative embodiments have been described in detail above. As will be evident to those skilled in the art, the present invention may be changed or modified in various ways within the technical scope of the invention. For example, the present disclosure can be applied to quartz-crystal oscillators that also include an IC configured as an oscillating circuit mounted inside the package on the package base.

What is claimed is:

1. A tuning-fork type quartz-crystal vibrating piece contained inside a package and bonded to respective connecting electrodes inside the package, the vibrating piece comprising:
a pair of vibrating arms extending in a predetermined direction and having respective excitation electrodes;
a base connected to the vibrating arms;
first and second supporting arms each disposed outboard of a respective vibrating arm and extending from the base in the predetermined direction; and
respective extraction electrodes extending from an edge region of each supporting arm to the respective excitation electrode; wherein
each excitation electrode comprises a first metal layer comprising at least one metal selected from Cr, Ni, Ti, Al and W, and a second metal layer overlying the first metal layer, the second metal layer comprising Au or Ag; and
each extraction electrode further comprises a third metal layer overlying the second metal layer and comprising at least one metal selected from Cr, Ni, Ti, Al and W, and a fourth metal layer overlying the third metal layer, the fourth metal layer comprising Au or Ag.

2. The vibrating piece of claim 1, wherein:
the second metal layer has a thickness in a range of 40 nm to 60 nm; and
the fourth metal layer has a thickness of at least 60 nm.

3. A quartz-crystal device, comprising:
a tuning-fork type quartz-crystal vibrating piece as recited in claim 1; and
respective external electrodes situated on an exterior surface of the package and connected to respective excitation electrodes.

4. A quartz-crystal device, comprising:
a tuning-fork type quartz-crystal vibrating piece as recited in claim 2; and
respective external electrodes situated on an exterior surface of the package and connected to respective excitation electrodes.

5. A tuning-fork type quartz-crystal vibrating piece including an outer frame bonded peripherally to a package base and including respective connecting electrodes, the vibrating piece comprising:
first and second supporting arms connected to the outer frame;
a base connected to the supporting arms;
first and second vibrating arms situated inboard of the respective supporting arm, each vibrating arm extending from the base and including respective excitation electrodes; and
respective extraction electrodes electrically connected to respective excitation electrodes, the extraction electrodes being situated on the base, the respective supporting arms, and the outer frame; wherein
each excitation electrode comprises a first metal layer comprising at least one metal selected from Cr, Ni, Ti, Al and W; and a second metal layer overlying the first metal layer, the second metal layer comprising Au or Ag; and
each extraction electrode further comprises a third metal layer overlying the second metal layer and comprising at least one metal selected from Cr, Ni, Ti, Al and W, and a fourth metal layer overlying the third metal layer and comprising Au or Ag.

6. A quartz-crystal device, comprising:
the quartz-crystal vibrating piece of claim 5;
a package base bonded onto a first surface of the outer frame; and
a package lid bonded onto a second surface of the outer frame.
